(19) United States
(12) Patent Application Publication
(10) Pub. No.: US 2015/0014652 A1
(43) Pub. Date: Jan. 15, 2015

(54) METHOD OF FABRICATING A SPUTTERING TARGET, SPUTTERING TARGET FABRICATED BY USING THE METHOD, AND AN ORGANIC LIGHT-EMITTING DISPLAY APPARATUS FABRICATED USING THE SPUTTERING TARGET

(71) Applicant: SAMSUNG DISPLAY CO., LTD., Yongin-City (KR)

(72) Inventors: Su-Hyuk Choi, Yongin-City (KR); Hun Kim, Yongin-City (KR); Jin-Woo Park, Yongin-City (KR)

(73) Assignee: SAMSUNG DISPLAY CO., LTD., Yongin-City (KR)

(21) Appl. No.: 14/194,653

(22) Filed: Feb. 28, 2014

(30) Foreign Application Priority Data
Jul. 12, 2013 (KR) 10-2013-0082444

(51) Int. Cl. C23C 14/34; H01L 51/52

(52) U.S. Cl. CPC C23C 14/3414; H01L 51/5243
USPC 257/40; 204/298.13; 264/646

(57) ABSTRACT

A method of fabricating a sputtering target, a sputtering target fabricated by the method, and an organic light-emitting display apparatus fabricated by using the sputtering target. The sputtering target may be used for forming a thin film encapsulation layer. The sputtering target includes tin oxide as a main component, and a copper fluoride compound as a dopant.

### CROSS-REFERENCE TO RELATED APPLICATION

This application claims priority to and the benefit of Korean Patent Application No. 10-2013-0082444, filed on Jul. 12, 2013, in the Korean Intellectual Property Office, the entire content of which is incorporated herein by reference.

### BACKGROUND

1. Field

One or more embodiments of the present invention relate to a method of fabricating a sputtering target, a sputtering target fabricated by the method, and an organic light-emitting display apparatus fabricated using the sputtering target.

2. Description of the Related Art

An organic light-emitting display apparatus is a light-emitting apparatus which may have a large viewing angle, good contrast, rapid response time, good luminance, and good driving voltage properties and response time. Additionally, an organic light-emitting display apparatus may be polychromatic.

The organic light-emitting apparatus may include an organic light-emitting device. The organic light-emitting device may be negatively impacted by moisture and oxygen. Thus, the organic light-emitting display apparatus commonly includes an encapsulating structure for encapsulating the organic light-emitting device to prevent or reduce penetration of moisture and/or oxygen. The encapsulating structure may include a thin film encapsulation layer. The thin film encapsulation layer may by formed by sputtering, using an inorganic material. In the sputtering, a sputtering target may be a cathode and a substrate for forming a layer may be an anode. That is, the target commonly maintains a negative potential with respect to the substrate. Thus, cationic materials may be accelerated toward, and collide with the sputtering target so that atoms of the target are emitted. When the material for forming the thin film encapsulation is formed of an insulating inorganic material, the sputtering target may also be formed of the insulating inorganic material. However, in this case, the resistance of the target may be large, and the forming rate of a layer through sputtering may be slow.

### SUMMARY

One or more embodiments of the present invention include a method of fabricating a sputtering target, in which a layer may be formed using an insulating material through a sputtering method, a sputtering target fabricated by the method, and an organic light-emitting display apparatus including the layer formed using the sputtering method.

Additional aspects are set forth in the following detailed description or will be apparent from the description.

According to an embodiment of the present invention, a sputtering target for forming a thin film encapsulation layer includes a tin oxide and a copper fluoride compound.

In one embodiment, the copper fluoride compound further includes a transition metal other than copper (Cu).

In one embodiment, the copper fluoride compound is CuF₂.

In one embodiment, the sputtering target further includes a conductive matrix. The conductive matrix includes nanoparticles and the nanoparticles include the copper fluoride compound.

In one embodiment, the sputtering target further includes a phosphorus oxide, boron phosphate, a niobium oxide, a silicon oxide, a tungsten oxide, a zinc oxide and/or a boron oxide.

In one embodiment, a resistivity of the sputtering target is smaller than a resistivity of the tin oxide.

According to a further embodiment, a method of fabricating a sputtering target includes mixing a first powder material including a tin oxide with a second powder material including a copper fluoride compound to prepare a mixture, and compressing and sintering the mixture in a reducing atmosphere.

In one embodiment, the method further includes preparing the first powder material before mixing the first powder material with the second powder material. In one embodiment, the preparing of the first powder material includes mixing a first raw material including the tin oxide with a second raw material including a phosphorus oxide, boron phosphate, a niobium oxide, a silicon oxide, a tungsten oxide, a zinc oxide and/or a boron oxide. In one embodiment, the mixing of the first raw material with the second raw material occurs in an atmosphere with reduced or no moisture, to prepare a raw material mixture. In one embodiment, the method further includes melting the raw material mixture in a reduced pressure atmosphere, the reduced pressure atmosphere being at a pressure lower than standard atmospheric pressure and being substantially oxygen-free and moisture-free, to prepare a molten material.

In one embodiment, the method further includes solidifying and pulverizing the molten material.

In one embodiment, the copper fluoride compound further includes a transition metal other than copper (Cu).

In one embodiment, the second powder material further includes a conductive matrix and the conductive matrix includes nanoparticles. In one embodiment, the nanoparticles include the copper fluoride compound.

In one embodiment, the mixture includes about 80 wt % to about 99 wt % of the first powder material and about 1 wt % to about 20 wt % of the second powder material.

In one embodiment, the sintering includes heating the mixture by high frequency induction heating.

In one embodiment, the compressing includes pressurizing the mixture with a metal plate.

According to a further embodiment, an organic light-emitting display apparatus includes a substrate; an organic light-emitting unit including a stack of a first electrode, an organic light-emitting layer, and a second electrode on the substrate; and a thin film encapsulation layer encapsulating the organic light-emitting unit, the thin film encapsulation layer including a tin oxide and a copper fluoride compound.

In one embodiment, the copper fluoride compound is CuF₂.

In one embodiment, the thin film encapsulation layer further includes a phosphorus oxide, boron phosphate, a niobium oxide, a silicon oxide, a tungsten oxide, a zinc oxide and/or a boron oxide.

In one embodiment, the thin film layer covers an upper surface and a side surface of the organic light-emitting unit.

According to aspects of embodiments of the present invention, a copper fluoride compound may be added into a target including an insulating inorganic material to provide conductivity and to improve sputtering efficiency of the insulating inorganic material.

According to aspects of embodiments of the present invention, barrier properties of a thin film encapsulation layer may be increased by including a copper fluoride compound, for example, instead of a tin fluoride compound into the tin oxide.

According to aspects of embodiments of the present invention, because copper fluoride has higher binding energy (i.e., a binding energy between Cu and F) than tin fluoride (i.e., a binding energy between Sn and F), decomposition of fluoride to form fluorine may be reduced during forming a layer.

### BRIEF DESCRIPTION OF THE DRAWINGS

These and/or other aspects of embodiments of the present invention will become more apparent from the accompanying drawings, which together with the specification, illustrate embodiments of the present invention, and serve to explain the principles of the present invention. In the drawings:

FIG. 1 is a flow chart illustrating a method of fabricating a sputtering target in accordance with an example embodiment of the present invention;

FIG. 2 is a schematic diagram illustrating an apparatus used for fabricating the sputtering target in accordance with an example embodiment of the present invention;

FIG. 3 is a schematic diagram illustrating the sputtering target fabricated in accordance with an example embodiment of the present invention;

FIGS. 4A and 4B are schematic diagrams illustrating the sputtering target fabricated in accordance with another example embodiment of the present invention;

FIG. 5 is a schematic diagram illustrating an organic light-emitting display apparatus including a thin film encapsulation layer manufactured by using the sputtering target in accordance with an example embodiment of the present invention; and

FIG. 6 is a schematic diagram showing a cross-sectional view of portion I in the example embodiment of FIG. 5.

### DETAILED DESCRIPTION

In the following detailed description, only certain embodiments of the present invention are shown and described, by way of illustration. As those skilled in the art would recognize, the invention may be embodied in many different forms and should not be construed as being limited to the embodiments set forth herein. Accordingly, embodiments are described below by way of example, by referring to the figures, to explain some aspects of, and embodiments of the present invention.

As used herein, the term “and/or” includes any and all combinations of one or more associated list of items. Expressions such as “at least one of,” when preceding a list of elements, modify the entire list of elements and do not modify the individual elements of the list.

Hereinafter, certain embodiments of the present invention are described with reference to the drawings. In the drawings, like reference numerals designate like elements throughout the specification. That is, like elements are referred to using the same reference numerals or symbols. Repeated explanations of like elements may be omitted. For ease, of understanding and illustration, the sizes and/or thicknesses of elements in the drawings may be exaggerated or reduced, and thus embodiments of the present invention are not limited to the sizes and/or thickness illustrated therein. That is, embodiments of the present invention are not limited to the absolute size and/or thickness of any given element shown in the drawings, and embodiments of the present invention are also not limited to a relative size and/or thickness of an element with respect to any other element shown in the drawings.

Also, in the context of the present application, when a layer, region, and/or element is referred to as being “on” another layer, region, and/or element, the layer, region, and/or element can be directly on the other layer, region and/or element or can be indirectly on the other layer, region and/or element, with an intervening layer therebetween.

As used herein, singular forms such as “a,” “an” and “the” are intended to include plural forms as well, unless the context clearly indicates otherwise. It will be further understood that terms such as “comprises,” “comprising,” and the like, when used in this specification, indicate the presence of recited features, elements, and/or components (e.g., regions and/or layers), but do not preclude the presence or additional features, elements, and/or components. It will be understood that, although terms such as “first” and “second,” may be used herein to describe various elements, layers, or the like, that these elements are not be limited by these terms. These terms are only used to distinguish one element, layer, or the like from one another.

Additionally, methods according to embodiments of the present invention are not limited the disclosed embodiments. For example, when an embodiment may be accomplished by a method alternative to a specifically disclosed method, any such alternative method is included within the scope of the present invention. For example, a method as described herein may be suitably modified, for example, by performing certain processes or steps sequentially rather than concurrently, by changing an order in which certain processes or steps are performed, or by including additional processes or steps, but modifications are not limited thereto.

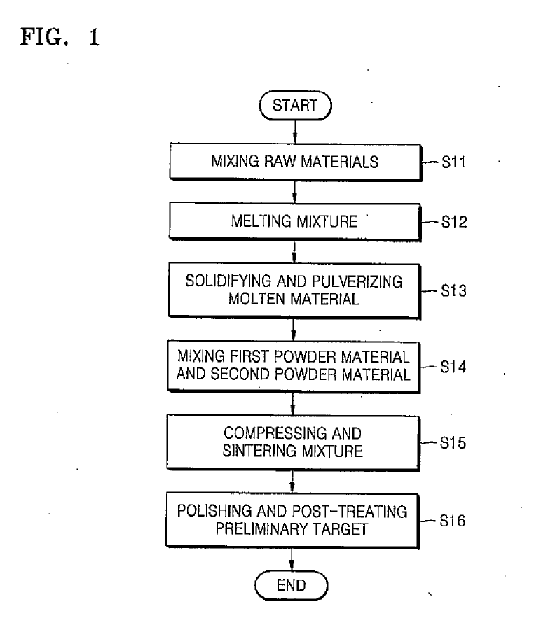

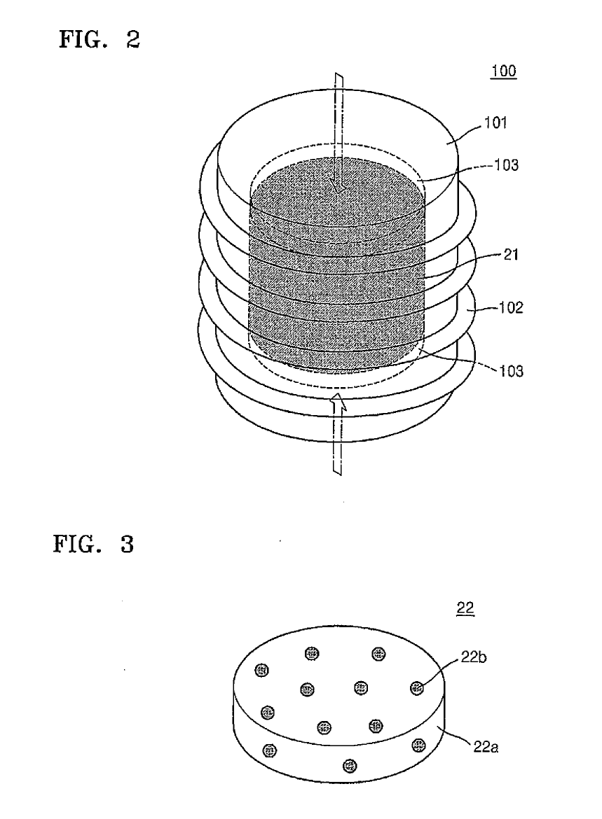

FIG. 1 is a flow chart illustrating a method of fabricating a sputtering target in accordance with an example embodiment of the present invention. FIG. 2 is a schematic diagram illustrating an apparatus used for fabricating a sputtering target in accordance with an example embodiment of the present invention.

Referring to FIG. 1, a method of fabricating a sputtering target in accordance with an example embodiment includes preparing a first powder material.

According to some embodiments, the first powder material is a material including one or more compounds, and being in the form of powder.

The first powder material may be a low temperature viscosity transition (LVT) inorganic material, that is, an inorganic material having a low temperature of viscosity transition. As used herein, the “temperature of viscosity transition” refers to a lowermost temperature at which the LVT inorganic material exhibits fluidity. That is, the “temperature of viscosity transition” does not necessarily refer to the temperature at which the LVT inorganic material completely changes from a “solid” to a “liquid.”

According to embodiments of the present invention, the temperature of viscosity transition of the LVT inorganic material is lower than a transforming temperature of an organic light-emitting unit included in an organic light-emitting display apparatus. That is, according to embodiments of the present invention, the temperature of the viscosity transition of the first powder material may be lower than the transforming temperature of the organic light-emitting unit based on the components (e.g., the compounds) included in the first powder material. When a layer is formed using a material having a higher temperature of viscosity transition than the transforming temperature of the organic light-emitting unit, the temperature of viscosity transition of the layer to be formed may be higher than the transforming temperature of the organic light-emitting unit.

The transforming temperature of the organic light-emitting unit refers to a temperature capable of inducing a chemical and/or physical transformation of a material included in the organic light-emitting unit. For example, the temperature capable of inducing the chemical and/or physical transformation of the material may include, but is not limited to a glass transition temperature (Tg) of a material included in an organic layer of the organic light-emitting unit. By way of example, the glass transition temperature may be obtained by conducting a thermal analysis on the material included in the organic light-emitting unit, using a thermo gravimetric analysis (TGA) and differential scanning calorimetry (DSC). This glass transition temperature may be about 110 degrees Celsius or more.

The LVT inorganic material may include tin oxide. The LVT inorganic material may include one or compounds (e.g., one kind of compound or a mixture of two or more kinds of compounds).Thus, the first powder material may include at least tin oxide (for example, SnO or SnO₂). In addition to the tin oxide, the first powder material may include one or more additional compounds. Non-limiting examples such compounds include, a phosphorus oxide (for example, P₂O₅), boron phosphate (BPO₄), a niobium oxide (for example, NbO and Nb₂O₅), a silicon oxide (for example, SiO₂), a tungsten oxide (for example, WO₃), a zinc oxide (for example, ZnO) and a boron oxide (for example, B₂O₃). For example, the first powder material may include: SnO; SnO and P₂O₅; SnO, and BPO₄; SnO, P₂O₅ and NbO; SnO, P₂O₅, and WO₃; SnO, P₂O₅, and B₂O₃; SnO, P₂O₅, B₂O₃, and ZnO; or SnO, B₂O₃, ZnO, and SiO₂. However, the first powder material is not limited to these examples.

When the first powder material includes two or more compounds, various suitable ratios of the two or more compounds may be used. Non-limiting examples of the compounds and ratios thereof (in terms of mol %) which may be included in the first power include: SnO (about 80 mol %) and P₂O₅ (about 20 mol %); SnO (about 90 mol %) and BPO₄ (about 10 mol %); SnO (about 20-80 mol %), P₂O₅ (about 10-30 mol %) and NbO (about 1-5 mol %), in which the sum of SnO, P₂O₅ and NbO is about 100 mol %; SnO (about 20-80 mol %), P₂O₅ (about 10-30 mol %) and WO₃ (about 1-5 mol %), in which the sum of SnO, P₂O₅ and WO₃ is about 100 mol %; SnO (about 20-70 mol %), P₂O₅ (about 5-50 mol %) and B₂O₃ (about 5-50 mol %), in which the sum of SnO, P₂O₅ and B₂O₃ is about 100 mol %; SnO (about 20-70 mol %), P₂O₅ (about 5-50 mol %), B₂O₃ (about 5-50 mol %) and ZnO (about 5-20 mol %), in which the sum of SnO, P₂O₅, B₂O₃ and ZnO is about 100 mol %; and SnO (about 20-70 mol %), B₂O₃ (about 5-50 mol %), ZnO (about 5-20 mol %) and SiO₂ (about 5-20 mol %), in which the sum of SnO, B₂O₃, ZnO and SiO₂ is about 100 mol %.

By way of example and not of limitation, the first powder material may be prepared by the following method. A raw material mixture, including a mixture of two or more compounds may be obtained by mixing a first compound, for example, a first raw material including a tin oxide, with a second compound, for example a second raw material such as a phosphorus oxide (for example, P₂O₅), boron phosphate (BPO₄), a niobium oxide (for example, NbO and Nb₂O₅), a silicon oxide (for example, SiO₂), a tungsten oxide (for example, WO₃), a zinc oxide (for example, ZnO) and/or a boron oxide (for example, B₂O₃) (See e.g., S11 of FIG. 1). The raw material mixture may include any one of the compounds and/or related ratios already described above, but are not limited thereto.

The first raw material and the second raw material may be in powder form. The first raw material and the second raw material may be mixed in a moisture-free, substantially moisture-free, or reduced moisture environment. For example, the first raw material and the second raw material may be mixed in a vessel isolated from an external atmosphere, and which blocks or substantially blocks moisture (e.g. from air) from entering the isolated vessel (e.g., a glove box). In some embodiments, the second raw material, being highly reactive toward water, may be moisture-sensitive. As a result, if the first raw material and the second raw material are mixed in an open atmosphere (i.e., in an air atmosphere), moisture present in the open atmosphere may be absorbed by, and react with, the second raw material, and thus chemically modify the second raw material. In order to prevent a reaction between the second raw material and the moisture (e.g., water vapor), the mixing of the first raw material and the second material may be performed in a glove box to block moisture from entering.

Then, a molten material may be prepared by melting the raw material mixture (See e.g., S12 of FIG. 1).

According to some embodiments, because the raw material mixture includes an LVT inorganic material, the melting may be performed at a relatively low temperature. When the raw material mixture is molten in an environment including moisture and oxygen, impurities may be included. Thus, in some embodiments, the melting may be performed in a reduced pressure atmosphere, e.g. using a vacuum, which excludes (or substantially excludes) moisture and/or oxygen the environment in which the melting is performed. Pressure may be varied according to the particular compounds included in the raw material mixture.

Then, the molten material may be solidified and pulverized to prepare a first powder material (See e.g., S13 of FIG. 1).

The molten material may be rapidly cooled to room temperature to form a solidified material. For example, the rapid cooling of the molten material may be performed using a same or similar method to that used for forming glass. The solidified material may be coarsely pulverized, and then finely pulverized, to obtain the first powder material.

The obtained first powder material may then be mixed with a second powder material to prepare a mixture (See e.g., S14 of FIG. 1).

The first powder material may include one of various oxides, such as tin oxide. Because metal cations and oxygen anions form strong relatively covalent bonds in these inorganic materials, the first powder material may be an insulating material having a large resistance. A sputtering target fabricated using only the first powder material, may thus have a large resistance, i.e., a small conductivity, which may reduce the yield of a layer formed using such a sputtering target.

According to embodiments of the present invention, the first powder material is mixed with the second powder material when fabricating the sputtering target to obtain a sputtering target having a small resistance and suitable conductivity.

In one embodiment, the second powder material includes a copper fluoride compound. The copper fluoride compound refers to a compound including copper (Cu) and fluorine (F). The copper fluoride compound may further include elements other than copper (Cu) and fluorine (F). In an example embodiment, the copper fluoride compound may further include a transition metal other than copper. Non-limiting examples of the copper fluoride compound include compounds having the formula CuₓMe_{y}F, in which x>y, and in which Me is a transition metal other than copper (e.g., Fe, Co, Ni and/or Zn). In another example embodiment, the copper fluoride compound is CuF₂. However, the copper fluoride material is not limited to these examples.

In an example embodiment, the copper fluoride compound may be in the form of nanoparticles. In some embodiments, the copper fluoride compound may be included as part of a nanocomposite material. For example, nanoparticles comprising the copper fluoride compound may be included in a conductive matrix, to form a nanocomposite material. The conductive material may include a transition metal such as titanium (Ti), vanadium (V), molybdenum (Mo), nickel (Ni), and/or the like. However, the conductive material is not limited to these materials. The nanoparticles comprising the copper fluoride compound may have an average diameter of about 1 nm to about 100 nm, but the average diameter is not limited thereto.

According to some embodiments, the copper fluoride compound is conductive, and thus, the conductivity of the sputtering target may be improved by including the nanoparticles comprising the copper fluoride compound in the conductive matrix. Thus, according to some embodiments, adding the second powder material including the copper fluoride compound, may increase the conductivity of the sputtering target, and decrease the resistivity of the sputtering target. Since the copper fluoride compound has a low reactivity with oxygen, an electrical arc that may otherwise be generated by combining a fluoride compound with oxygen, during sputtering, may be prevented or reduced.

According to some embodiments, the mixture of the first powder material and the second material may include about 80 wt % to about 99 wt % of the first powder material and about 1 wt % to about 20 wt % of the second powder material. When an amount of the second powder material in the mixture is less than about 0.1 wt %, the conductivity of the sputtering target may be small. When an amount of the second powder material in the mixture exceeds about 10 wt %, it may be difficult to obtain a homogeneous mixture of the copper fluoride compound.

The mixture may then be compressed and sintered to prepare a preliminary target (See e.g., S15 of FIG. 1). The mixture may be compressed, for example, by pressurizing the mixture. The mixture may be sintered, for example, by cementation (e.g., through heating a molded powder body into a certain shape to closely adhere to the powder body to the shape). In accordance with an example embodiment of the present invention, the compression and the sintering of the mixture may be performed together (e.g., at the same time) to prepare the preliminary target.

When the preliminary target is formed by compressing and sintering the mixture at the same time, a processing time may be decreased when compared to a method of sequentially compressing and sintering the mixture. For example, when the preliminary target is formed by compressing followed by sintering, the shape of the preliminary target may not be maintained, and instead may be easily broken. However, when the preliminary target is formed by compressing and sintering at the same time, the shape of the preliminary target may be completely or substantially maintained.

In FIG. 2, a target fabricating apparatus 100 for forming the preliminary target is illustrated. The target fabricating apparatus 100 includes a container 101 (for example, a crucible) for receiving a mixture 21, a heating unit for heating the mixture 21, and a plate 103 for pressurizing the mixture 21. Hereinafter, a method of forming a preliminary target using the target fabricating apparatus 100 will be described with reference to FIG. 1.

In accordance with an example embodiment of the present invention, the preliminary target is formed in a reducing atmosphere. Reducing of, or reduction of a compound (i.e., by a reduction reaction), may refer to releasing oxygen or eliminating oxygen from an oxide compound. Thus, according to some embodiments, in the reducing atmosphere, oxygen included in the mixture is eliminated.

According to some embodiments, oxygen included in the oxide may be eliminated in the reducing atmosphere, and metal cations (for example, Sn²⁺) may be present in the mixture. According to some embodiments, as a result of the reducing atmosphere, Sn²⁺ remains present in the mixture, as a network-modifier oxide. Sn²⁺ may react with oxygen in the atmosphere after forming a layer, to form Sn⁴⁺, present along with phosphorus and boron. According to some embodiments, when the compressing and the sintering are conducted together (e.g., at the same time), a strongly cemented (e.g., being durable and/or firm) preliminary target may be formed, even without using a binder material.

When a binder is used to fabricate a strongly cemented target, the binder may contaminate a layer formed thereon, and may thus introduce an impurity into the formed layer, which may deteriorate the transmittance and/or purity of the layer. However, when a target is fabricated without using a binder, the target may not be strongly cemented, and thus the shape of the target may not be suitably maintained and target may be more easily broken. By fabricating the preliminary target in the reducing atmosphere as in the example embodiments of the present invention, the fabricated target may be rich in Sn²⁺, that is, the target may include an amount of Sn²⁺ suitable to provide a strongly cemented target without using a binder. Thus, according to some embodiments, a thin film formed on the target may exclude (or substantially exclude) impurities during its formation, even when the compressing and the sintering are performed at the same time.

The preliminary target may be sintered at a high temperature of about 200 degrees to about 450 degrees Celsius. The sintering may be performed using a high frequency induction heating method. For example, in the high frequency induction heating, a conductive material of a target object may be placed in a coil, and a high frequency may be applied to the coil. Then, an eddy current may be generated near the conductive material, and the target object may be heated by heat emitted from the coil.

Referring to the target fabricating apparatus 100 in FIG. 2, a coil 102 corresponding to a heating unit is at an outer surface of the container 101. A high frequency is applied to the coil 102 to heat the container 101 and to heat a mixture included in the container 101. When the heating is conducted by the high frequency induction heating method, the heat may be uniformly transferred, that is, the uniformity of the heat transferred to the surface and an inner portion of the preliminary target may be improved when compared with other heating methods.

The preliminary target may be compressed with a pressure of about 250 kgf/cm² to about 350 kgf/cm². The compression may be conducted using plates 103 as shown in FIG. 2.

Referring to the target fabricating apparatus 100 in FIG. 2, two plates 103 are included, one at an upper surface of the container 101 and the other at a lower surface of the container 101. The mixture 21, between the two plates 103, may be gradually compressed by decreasing the distance between the two plates 103. In FIG. 2, the mixture may be compressed from both sides of the mixture 21. However, the present invention is not limited thereto. For example, pressure may be applied to the mixture 21 from only one side with another side being stationary. Plates 103 may be formed of a material having a high thermal conductivity and corrosion-resistance, such as a stainless steel (SUS).

Then, the preliminary target may be polished and post-treated to fabricate a sputtering target (See e.g., S16 of FIG. 1). For example, a surface of the preliminary target may be polished to remove any foreign materials (e.g., particles or other impurities), and the preliminary target may be attached to a packing plate of a sputtering apparatus, to fabricate the sputtering target.

FIG. 3 is a schematic diagram illustrating a sputtering target 22 fabricated in accordance with an example embodiment of the present invention.

Referring to FIG. 3, a sputtering target 22 in accordance with an example embodiment of the present invention includes a first powder material 22a and a copper fluoride compound 22b. The first powder material may include a Sn—P—O-based material, for example, SnO (e.g., about 80 mol %) and P₂O₅ (e.g., about 20 mol %). The copper fluoride compound 22b may include CuF₂.

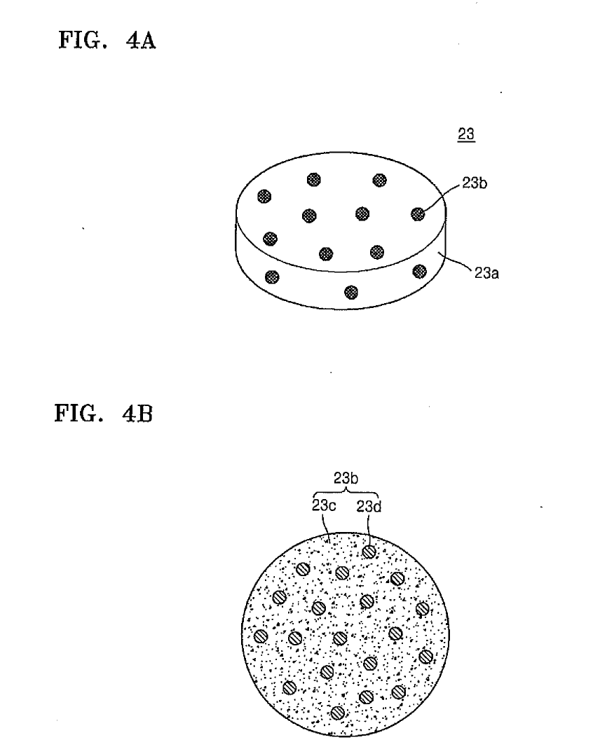

FIGS. 4A and 4B are schematic diagrams illustrating a sputtering target 23 fabricated in accordance with another example embodiment of the present invention.

Referring to FIG. 4A, the sputtering target 23 in accordance with an example embodiment of the invention includes a first powder material 23a and a copper fluoride nanocomposite 23b. The first powder material 23a may include a Sn—P—O-based material, for example, SnO (about 80 mol %) and P₂O₅ (about 20 mol %). The copper fluoride nanocomposite 23b may include CuF₂.

Referring to FIG. 4B, the copper fluoride nanocomposite 23b includes nanoparticles 23d in a conductive matrix 23c. The nanoparticles 23d comprise the copper fluoride compound. In these embodiment, an average diameter of the nanoparticles 23d may be about 1 nm to about 100 nm, but the diameter of the nanoparticles 23d are not limited thereto. The conductive matrix 23c may include a transition metal. Non-limiting examples of the transition metal include titanium (Ti), vanadium (V), molybdenum (Mo), nickel (Ni), and the like.

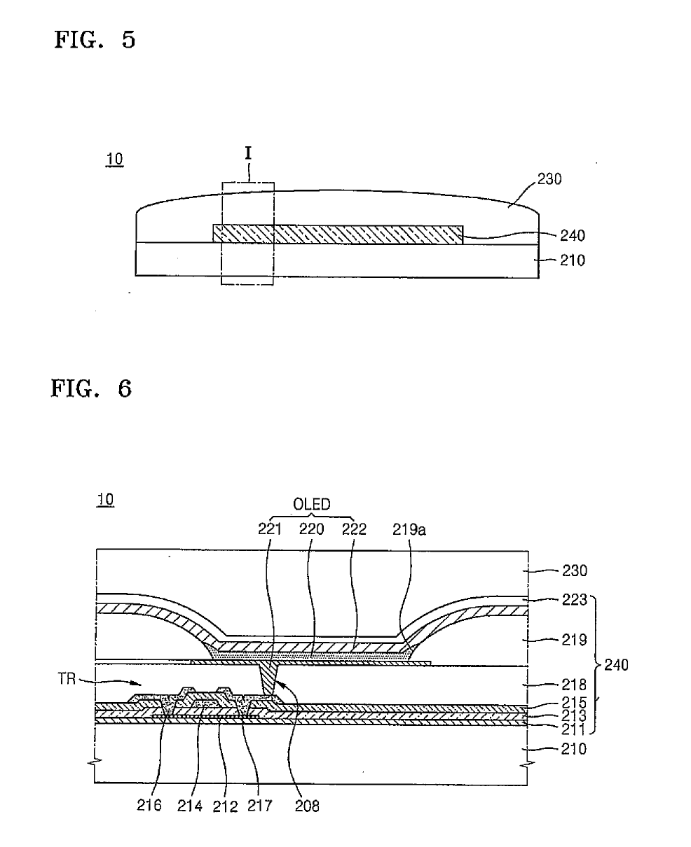

FIG. 5 is a schematic diagram illustrating an organic light-emitting display apparatus 10 including a thin film encapsulation layer 230 manufactured using a sputtering target in accordance with an example embodiment of the present invention. FIG. 6 is a schematic diagram illustrating a cross-sectional view of portion I in the example embodiment of FIG. 5.

Referring to FIGS. 5 and 6, the organic light-emitting display apparatus 10 in accordance with an example embodiment of the present invention includes, a substrate 210, an organic light-emitting unit 240 on the substrate 210, and a thin film encapsulation layer 230 for encapsulating the organic light-emitting unit 240, the thin film encapsulation layer 230 including tin oxide and a copper fluoride compound.

The substrate 210 may be formed using a material such as transparent glass including SiO₂ as a main component. However, the material of the substrate 210 is not limited thereto, and the substrate may be formed of various other suitable materials such as ceramics, transparent plastics, metal materials, or the like. When the organic light-emitting display apparatus is a top emission type display, emitting light in a direction away from the substrate 210, the substrate 210 may be made of any suitable material, and being a top emission type display, may include opaque materials, but is not limited to opaque materials. Non-limiting examples of the substrate 210 include a metal substrate, a carbon fiber substrate other than the glass substrate, or a plastic substrate. When the organic light-emitting display apparatus is a flexible display apparatus, the substrate 210 may be made of, for example, a flexible substrate (e.g., formed of a flexible polyimide film capable of bending).

A buffer layer 211 may be formed on the substrate 210. The buffer layer 211 may provide a planar surface on an upper portion of the substrate 210. The buffer layer 211 may include an insulating material to prevent or reduce penetration of moisture and/or foreign materials in a direction of the substrate 210.

To fabricate an OLED, a thin film transistor TR and/or a capacitor may be included on the buffer layer 211. The thin film transistor TR may include an active layer 212, a gate electrode 214, and source/drain electrodes 216 and 217. The organic light-emitting device OLED may include a first electrode 221, a second electrode 222, and an intermediate layer 220.

In one embodiment, the active layer 212 may be formed as a pattern on an upper surface of the buffer layer 211. The active layer 212 may include an inorganic semiconductor material such as silicon, an organic semiconductor material, or an oxide semiconductor material, and may be doped with p-type or n-type dopants.

A gate insulating layer 213 may be formed on the active layer 212. The gate electrode 214 on the active layer 212 may be formed on the gate insulating layer 213.

An interlayer insulating layer 215 may be formed on, and cover, the gate electrode 214. The source/drain electrodes 216 and 217 may be formed on the interlayer insulating layer 215. The source/drain electrodes 216 and 217 may contact a region of the active layer 212.

A planarization layer 218 may be formed on, and cover the source/drain electrodes 216 and 217. In one embodiment, a further insulating layer may be formed on the planarization layer 218.

The first electrode 221 may be formed on the planarization layer 218. The first electrode 221 may make an electric contact with one of the source/drain electrodes 216 or 217 through a penetration hole 208.

A pixel defining layer 219 may be formed on, and cover the first electrode 221. An opening portion 219a may be formed in the pixel defining layer 219. The intermediate layer 220, including an organic light-emitting layer, may be formed within a region defined by the opening portion 219a. The pixel defining layer 219 may include a pixel region and a non-pixel region. The opening portion 219a of the pixel defining layer 219 may be substantially a pixel region.

The intermediate layer 220 may further include a hole injection layer (HIL), a hole transport layer (HTL), an electron transport layer (ETL), and/or an electron injection layer (EIL), in addition to the organic light-emitting layer.

The second electrode 222 may be formed on the intermediate layer 220. The first electrode 221 may be patterned for each pixel, and the second electrode 222 may be suitably formed to apply a common voltage through all of the pixels.

In the drawings, only one organic light-emitting device OLED is illustrated. However, the display apparatus 100 may include a plurality of the organic light-emitting devices OLED. For example, one pixel may be formed for each of the organic light-emitting devices OLED, and each of the pixels may emit, red, green, blue or white light.

However, the display apparatus 100 according to embodiments of the present disclosure is not limited thereto. For example, the intermediate layer 220 may be commonly formed on the entire planarization layer 218, irrespective of a position of the pixel. In this example, the organic light-emitting layer may be formed by vertically stacking and/or mixing light emitting layers (i.e., layers including light emitting materials emitting, for example, materials suitable to emit red, green and/or blue light). In these embodiments, emission of other colors of light may be possible, for example, when white light is emitted, and a color transforming layer or a color filter is used (e.g., by transforming the emitted white light into a light of a desired color by passing through the color transforming layer or color filter.

A passivation layer 223 may be included on the organic light-emitting device OLED and the pixel defining layer 219. The passivation layer 223 may passivate the organic light-emitting device OLED to protect the OLED, for example, by covering the OLED. The passivation layer 223 may be formed of an inorganic insulating layer and/or an organic insulating layer.

The thin film encapsulation layer 230 may prevent the penetration of external moisture or oxygen into the organic light-emitting unit 240. That is, the thin film encapsulation layer 230 may encapsulate the organic light-emitting unit 240 to protect the organic light-emitting unit 240 from an external environment (e.g., the atmosphere), which may contain moisture and/or oxygen.

The thin film encapsulation layer 230 may include tin oxide and a copper fluoride compound. The thin film encapsulation layer 230 may include an LVT inorganic material. Thus, according to some embodiments, the temperature of viscosity transition of the thin film encapsulation layer 230 may be lower than the transforming temperature of a material included in the organic light emitting unit 240. Transforming temperatures of materials included in the organic light emitting unit 240 may exceed, for example, about 130° C., but the transforming temperatures of these materials are not limited thereto. In some example embodiments, the temperature of viscosity transition of the LVT inorganic material may be about 80° C. or more, for example, about 80° C. to about 130° C. or about 80° C. to about 120° C., but the temperature of viscosity transition of the LVT inorganic material is not limited thereto.

The thin film encapsulation layer 230 may further include a phosphorus oxide, boron phosphate, a niobium oxide, a silicon oxide, a tungsten oxide, a zinc oxide and/or a boron oxide.

Additional components may be included in the thin film encapsulation layer 230, for example, to control or adjust the temperature of the viscosity transition of the thin film encapsulation layer 230. For example, a tin fluoride (for example, SnF₂) may be included to lower the temperature of viscosity transition of the thin film encapsulation layer 230. However, during formation of a layer (e.g., an encapsulation layer) by sputtering, the tin fluoride may decompose, generating molecular fluorine (i.e., fluorine gas, F₂), which may be harmful to the environment.

According to embodiments of the present invention, the copper fluoride compound included in the thin film encapsulation layer 230 may lower the temperature of viscosity transition of the thin film encapsulation layer 230, while preventing or reducing the generation of fluorine gas during formation of a layer (e.g., during formation of the thin film encapsulation layer 230).

The binding energy of the copper fluoride compound is larger than that of the tin fluoride (SnF₂). For example, the binding energy of copper fluoride (CuF₂) is about 936 eV and is about twice that of tin fluoride (SnF₂), which has a binding energy of about 487 eV. As consequence, the copper fluoride compound is less reactive than SnF₂ toward oxygen and/or moisture. Accordingly, in some embodiments, the barrier properties of the thin film encapsulation layer 230 may be enhanced. According to some embodiments, because a decomposition reaction producing fluorine during the formation of the thin film encapsulation layer 230 including the copper fluoride compound is prevented or reduced, a resulting impact on the environment may be reduced.

Non-limiting examples of compounds included in the thin film encapsulation layer 230 include: SnO and CuF₂; SnO, CuF₂ and P₂O₅; SnO, CuF₂ and BPO₄; SnO, P₂O₅, CuF₂ and NbO; or SnO, P₂O₅, CuF₂ and WO₃.

In an example embodiment, the thin film encapsulation layer 230 may include about 80 to about 99 wt % of SnO—P₂O₅, and from about 1 to about 20 wt % of CuF₂. However, the thin film encapsulation layer is not limited thereto.

A thickness of the thin film encapsulation layer 230 may be about 1 μm to about 30 μm, for example, from 1 μm to about 5 μm. When the thickness of the thin film encapsulation layer 230 has a thickness of about 1 μm to about 5 μm, an organic light-emitting display apparatus 10 may be flexible, that is, being capable of bending.

The thin film encapsulation layer 230 may cover an upper surface and a side surface of the organic light-emitting unit 240. In these embodiments, the thin film encapsulation layer 230 may prevent or reduce oxygen and/or moisture (e.g., from an external environment, such as the atmosphere) from entering through the upper surface and the side surface of the organic light-emitting unit 240.

While the present invention has been described in connection with certain embodiments, it is to be understood that the invention is not limited to the disclosed embodiments, but, on the contrary, is intended to cover various modifications and equivalent arrangements included within the spirit and scope of the appended claims, and equivalents thereof. Further, while embodiments of the present invention have been described with reference to the figures, it will be understood by those of ordinary skill in the art, that various changes may be made without departing from the spirit and scope of the present invention. Additionally, descriptions of features or aspects within each embodiment may be considered as also referring to other similar features or aspects in other embodiments.

What is claimed is:

1. A sputtering target for forming a thin film encapsulation layer, the sputtering target comprising a tin oxide and a copper fluoride compound.

2. The sputtering target of claim 1, wherein the copper fluoride compound further comprises a transition metal other than copper (Cu).

3. The sputtering target of claim 1, wherein the copper fluoride compound is CuF₂.

4. The sputtering target of claim 1, further comprising a conductive matrix, wherein:
the conductive matrix comprises nanoparticles; and
the nanoparticles comprise the copper fluoride compound.

5. The sputtering target of claim 1, further comprising at least one selected from the group consisting of a phosphorus oxide, boron phosphate, a niobium oxide, a silicon oxide, a tungsten oxide, a zinc oxide and a boron oxide.

6. The sputtering target of claim 1, wherein a resistivity of the sputtering target is smaller than a resistivity of the tin oxide.

7. A method of fabricating a sputtering target, the method comprising:
mixing a first powder material including a tin oxide with a second powder material including a copper fluoride compound to prepare a mixture; and
compressing and sintering the mixture in a reducing atmosphere.

8. The method of claim 7, further comprising preparing the first powder material before mixing the first powder material with the second powder material, the preparing of the first powder material comprising:
mixing a first raw material including the tin oxide with a second raw material including at least one selected from the group consisting of a phosphorus oxide, boron phosphate, a niobium oxide, a silicon oxide, a tungsten oxide, a zinc oxide and a boron oxide, wherein the mixing of the first raw material with the second raw material occurs in an atmosphere with reduced or no moisture, to prepare a raw material mixture;
melting the raw material mixture in a reduced pressure atmosphere, the reduced pressure atmosphere being at a pressure lower than standard atmospheric pressure and being substantially oxygen-free and moisture-free, to prepare a molten material; and
solidifying and pulverizing the molten material.

9. The method of claim 7, wherein the copper fluoride compound further comprises a transition metal other than copper (Cu).

10. The method of claim 7, wherein:
the second powder material further comprises a conductive matrix;
the conductive matrix comprises nanoparticles; and
the nanoparticles comprise the copper fluoride compound.

11. The method of claim 7, wherein the mixture comprises about 80 wt % to about 99 wt % of the first powder material and about 1 wt % to about 20 wt % of the second powder material.

12. The method of claim 7, wherein the sintering comprises heating the mixture by high frequency induction heating.

13. The method of claim 7, wherein the compressing comprises pressurizing the mixture with a metal plate.

14. An organic light-emitting display apparatus comprising:
a substrate;
an organic light-emitting unit including a stack of a first electrode, an organic light-emitting layer, and a second electrode on the substrate; and
a thin film encapsulation layer encapsulating the organic light-emitting unit, the thin film encapsulation layer including a tin oxide and a copper fluoride compound.

15. The organic light-emitting display apparatus of claim 14, wherein the copper fluoride compound is CuF₂.

16. The organic light-emitting display apparatus of claim 14, wherein the thin film encapsulation layer further comprises at least one selected from the group consisting of a phosphorus oxide, boron phosphate, a niobium oxide, a silicon oxide, a tungsten oxide, a zinc oxide and a boron oxide.

17. The organic light-emitting display apparatus of claim 14, wherein the thin film layer covers an upper surface and a side surface of the organic light-emitting unit.
